(19) United States
(12) Patent Application Publication
(10) Pub. No.: US 2018/0127877 A1
(43) Pub. Date: May 10, 2018

(54) AREA-SELECTIVE ATOMIC LAYER DEPOSITION APPARATUS

(71) Applicant: KOREA UNIVERSITY RESEARCH AND BUSINESS FOUNDATION, Seoul (KR)

(72) Inventors: Joon Hyung SHIM, Seoul (KR); Hyung Jong CHOI, Jeonju-si, Jeollabuk-do (KR); Ki Ho BAE, Hanam-si, Gyeonggi-do (KR); Jun Woo KIM, Seoul (KR); Gwon Deok HAN, Seongnam-si, Gyeonggi-do (KR)

(73) Assignee: KOREA UNIVERSITY RESEARCH AND BUSINESS FOUNDATION, Seoul (KR)

(21) Appl. No.: 15/574,277

(22) PCT Filed: Feb. 26, 2016
(86) PCT No.: PCT/KR2016/001938

§ 371 Date: Nov. 15, 2017

(30) Foreign Application Priority Data
May 15, 2015 (KR) 10-2015-0068010

(51) Int. Cl. C23C 16/48; C23C 16/455; C23C 16/04; C23C 16/44

(52) U.S. Cl. CPC C23C 16/483; C23C 16/4408; C23C 16/047; C23C 16/45544

(57) ABSTRACT

The present invention provides a selective area atomic layer deposition apparatus that deposits an atomic layer thin film on a substrate by supplying a source gas and a purge gas, the apparatus comprising: a reaction chamber; a stage disposed within the reaction chamber, a substrate being disposed on one surface of the stage; a combination nozzle unit disposed above the stage to move relative to the stage; and a gas supply unit that supplies a precursor and an oxidant for forming an atomic layer thin film on the substrate, wherein the combination nozzle unit has a laser core that applies a laser beam to selectively locally heat one surface of the substrate, and the gas supply unit is disposed such that at least a part thereof is adjacent to the laser core, and supplies the precursor and the oxidant to the area on the surface of the substrate that is selectively locally heated by the laser core, wherein the precursor is adsorbed onto the heated area of the substrate, and the oxidant removes ligands of the precursor.

### TECHNICAL FIELD

The present invention relates to an area-selective atomic layer deposition apparatus, and more particularly, to an apparatus which enables a local area of a substrate to be heated using a laser, and simultaneously enables an atomic layer to be deposited on the local area of the substrate using a nozzle.

### BACKGROUND ART

In the manufacturing process of a general semiconductor device, a physical vapor deposition method, i.e., a sputtering method is widely used as a method of depositing various kinds of thin films on a semiconductor substrate. However, the sputtering method entails a drawback in that when a step is formed on the surface of the substrate, the step coverage referring to the ability to cover smoothly the substrate surface is deteriorated. Accordingly, recently, a chemical vapor deposition (CVD) method using a metal organic precursor has been widely used.

However, a thin film formation method employing the chemical vapor deposition method has an advantage in that it has an excellent step coverage and a high productivity, but still encounters a problem in that a thin film formation temperature is high and the thickness of the thin film cannot be controlled precisely in the unit of A. In addition, for the conventional thin film formation method, more than two reaction gases are simultaneously supplied into a reactor to cause a reaction in a gaseous state, resulting in generation of particles that are a pollution source.

In recent years, further minuteness of a semiconductor process leads to a reduction in the thickness of a thin film, which requires a precise control thereof. In particular, in order to overcome this limitation in various sections such as a dielectric film of a semiconductor device, a transparent conductor of a liquid crystal display element, or a protective layer of an electroluminescent thin film display element, and the like, an atomic layer deposition (ALD) method has been proposed as a method for forming a thin film having a minute thickness in the unit of an atomic layer.

Such an atomic layer deposition method is a method that forms a thin film by repeatedly performing a reaction cycle, several times, in which each reactant is separately injected into a substrate (i.e., a wafer) to allow the reactant to be chemically saturatedly adsorbed to the surface of the substrate.

The atomic layer deposition method is a process method in which a precursor and an oxidant are supplied to a substrate to remove ligands of the precursor adsorbed to the substrate using the oxidant to thereby deposit a thin film in the unit of the atomic layer on the substrate.

In this case, in the atomic layer deposition method, a precursor supplying-purging-oxidant supplying-purging process is mainly defined as one cycle for the deposition of an atomic layer. However, the atomic layer deposition method according to the prior art has a problem in that it employs a way of purging an excessive amount of precursor to react with the entire area of the substrate, making it impossible to control the area and position where the precursor comes into close contact with the substrate.

Therefore, the conventional atomic layer deposition method still involves a problem in that the selective formation of an atomic layer is required to be accompanied by the lithography and patterning process, making the entire process cumbersome and complicated to increase the process cost and the manufacturing time, ultimately resulting in an increase in the manufacturing cost of products.

### DISCLOSURE OF INVENTION

### Technical Problem

Accordingly, the present invention has been made to solve the above-mentioned problems occurring in the prior art, and it is an object of the present invention to provide an area-selective atomic layer deposition apparatus which enables an atomic layer thin film to be formed on a local area of a substrate.

### Technical Solution

To achieve the above object, the present invention provides an area-selective atomic layer deposition apparatus that deposits an atomic layer thin film on the surface of a substrate by supplying a source gas and a purge gas, the apparatus including: a reaction chamber; a stage disposed within the reaction chamber, and configured to allow a substrate (S) to be disposed on one surface thereof; a combination nozzle unit disposed above the stage so as to move relative to the stage; and a gas supply unit configured to supply a precursor and an oxidant for forming an atomic layer thin film on the substrate, wherein the combination nozzle unit includes a laser core configured to emit a laser beam to selectively locally heat one surface of the substrate, and wherein the gas supply unit is disposed such that at least a part thereof is adjacent to the laser core, and supplies the precursor and the oxidant to an area of the one surface of the substrate, which is selectively locally heated by the laser core, wherein the precursor is adsorbed onto the heated area of the substrate, and the oxidant removes the ligands of the precursor.

In the area-selective atomic layer deposition apparatus, the gas supply unit may include: a precursor supply line unit configured to supply the precursor; and an oxidant supply line unit configured to supply the oxidant.

In the area-selective atomic layer deposition apparatus, the gas supply unit may include a common supply section disposed at the combination nozzle unit and configured to form at least parts of the precursor supply line unit and the oxidant supply line unit, which are commonly overlapped with each other.

In the area-selective atomic layer deposition apparatus, the common supply section may be arranged at the outer circumference of the laser core.

In the area-selective atomic layer deposition apparatus, the common supply section may be concentrically arranged at the outer circumference of the laser core.

In the area-selective atomic layer deposition apparatus, the gas supply unit may further include a suction line unit including a suction section configured to suck in one or more of the precursor, the oxidant, and a precursor from which the ligands are removed by the oxidant.

In the area-selective atomic layer deposition apparatus, the suction section may be arranged at the outer circumference of the common supply section.

In the area-selective atomic layer deposition apparatus, the suction section may be concentrically arranged at the outer circumference of the common supply section.

In the area-selective atomic layer deposition apparatus, the precursor supply line unit and the oxidant supply line unit may include a supply line switching control valve configured to allow the precursor and the oxidant to be alternately supplied therethrough.

In the area-selective atomic layer deposition apparatus, the stage 110 may include a stage driving unit configured to move the stage in response to a movement control signal from the control unit.

### Advantageous Effects

The area-selective atomic layer deposition apparatus according to the present invention as constructed above have the following advantageous effects.

First, the area-selective atomic layer deposition apparatus according to an embodiment of the present invention performs a heating operation on a selective area of a substrate through a laser and supplies a precursor and an oxidant through a combination nozzle unit so that chemisorption of the precursor can be achieved through the supply of energy to a heated local area of the substrate, making it possible to form an atomic layer thin film on a selected local area on the substrate.

Second, the area-selective atomic layer deposition apparatus according to an embodiment of the present invention apparatus enables a local area of the substrate to be selectively heated through a laser core, and can implement a smoother atomic layer deposition method through a combination nozzle unit including a common supply section that supplies a precursor and an oxidant and a suction section that sucks in a gas residue such as re-recovering a precursor which does not react with the local area of the substrate.

Third, the area-selective atomic layer deposition apparatus according to an embodiment of the invention takes a structure in which a laser core, a common supply section, and a suction section are arranged concentrically and coaxially relative thereto, making compact the structure of the combination nozzle unit.

Fourth, the area-selective atomic layer deposition apparatus according to an embodiment of the present invention eliminates or minimizes the conventional lithography and patterning process to decrease the process time, leading to a reduction in the manufacturing cost.

Fifth, the area-selective atomic layer deposition apparatus according to an embodiment of the present invention eliminates an etching process such as lithography to minimize the amount of unnecessary chemical wastes generated so that an environmentally friendly manufacturing process can be provided.

Sixth, the area-selective atomic layer deposition apparatus according to an embodiment of the present invention locally heats a substrate to minimize thermal loss of the substrate that can be implemented as an electronic element, leading to the minimization of the occurrence of a defect due to a thermal residual stress and to the improvement of the performance of the element.

Seventh, the area-selective atomic layer deposition apparatus according to an embodiment of the present invention can remove a large-area heating plate provided on a conventional atomic layer deposition apparatus, resulting in a reduction in the process cost.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 is a schematic block diagram showing the configuration of an area-selective atomic layer deposition apparatus according to an embodiment of the present invention;

FIG. 2 is a schematic, partial cross-section view showing a combination nozzle unit of an area-selective atomic layer deposition apparatus according to an embodiment of the present invention; and

FIGS. 3 to 7 are manufacturing process charts showing a selective atomic layer thin film formation process of an area-selective atomic layer deposition apparatus according to an embodiment of the present invention.

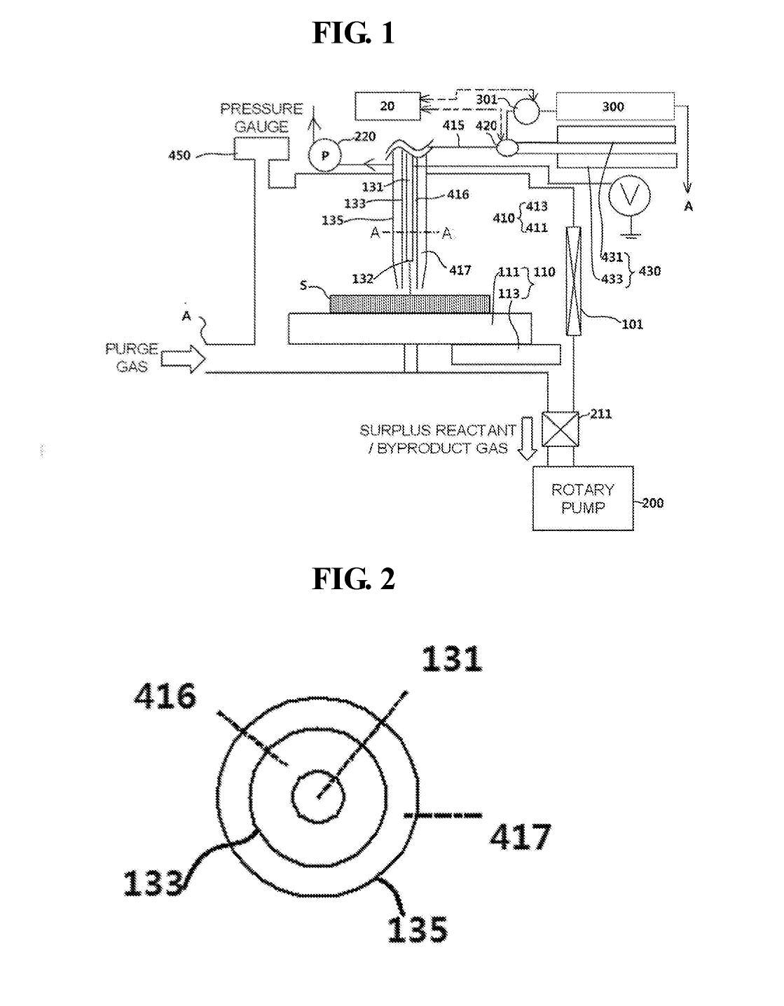

### DESCRIPTION OF THE PREFERRED EMBODIMENTS

Now, preferred embodiments of the present invention will be described hereinafter in detail with reference to the accompanying drawings. It should be noted that the same elements in the drawings are denoted by the same reference numerals although shown in different figures. In the following description, the detailed description on known function and constructions unnecessarily obscuring the subject matter of the present invention will be avoided hereinafter.

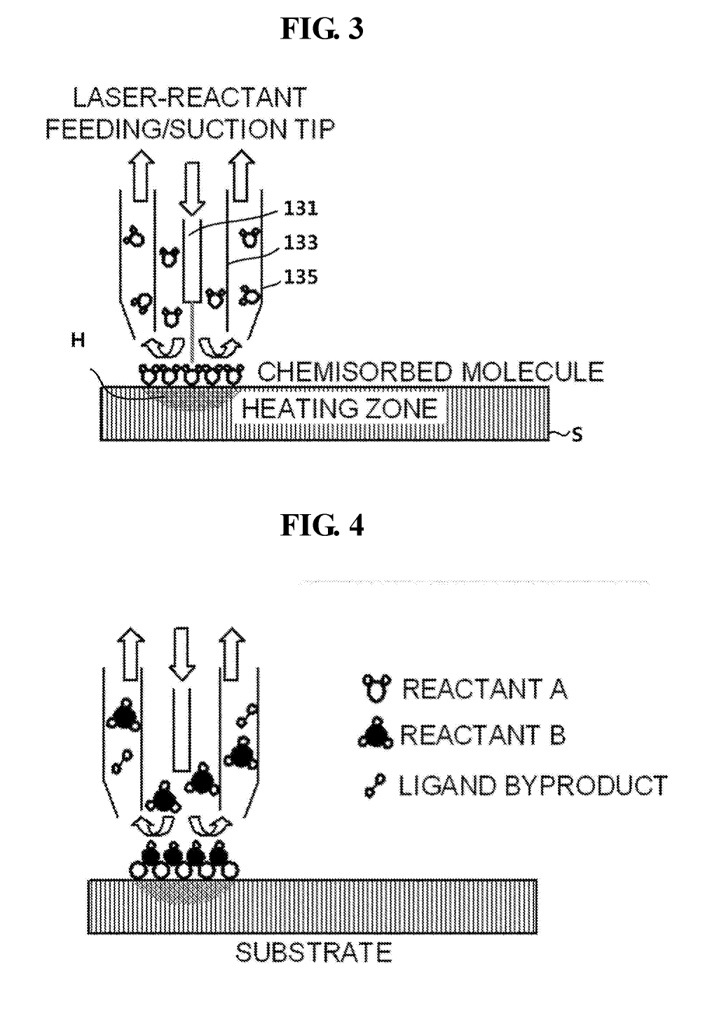

FIG. 2 is a schematic, partial cross-section view showing a combination nozzle unit of an area-selective atomic layer deposition apparatus according to an embodiment of the present invention, FIG. 3 is a schematic conceptual view showing the configuration and operational state of a gas line connector module of an area-selective atomic layer deposition apparatus according to an embodiment of the present invention, and FIG. 4 shows a view obtained by graphing the operation control scheme of an opening/closing valve of each gas line connector module of an area-selective atomic layer deposition apparatus according to an embodiment of the present invention.

The area-selective atomic layer deposition apparatus according to an embodiment of the present invention is an apparatus that deposits an atomic layer thin film on the surface of a substrate S, and includes a reaction chamber 100, a stage 110, a gas supply unit 120, and a combination nozzle unit 130.

The reaction chamber 100 is formed as a hermetically sealed space at an interior thereof. The reaction chamber 100 can include a reaction chamber window 101 disposed at the outer side thereof to check the interior thereof.

A chamber pump 200 is connected to the reaction chamber 100 so as to form an atmospherical state under a constant pressure condition of the interior of the reaction chamber 100.

The reaction chamber 100 is also connected to the gas supply unit 120 so that the atmosphere formation and pressure state of the interior of the reaction chamber 100 can be controlled through the connection of the gas supply unit 120 and the purge gas supply unit 300. In addition, a chamber pressure gauge 450 is connected to the reaction chamber 100 so that a pump operation control signal of the chamber pump 200 or a connection control signal of the purge gas supply unit 300 may be controlled by a control unit (not shown) by checking the pressure atmosphere of the interior of the reaction chamber 100 through the chamber pressure gauge 450.

The reaction chamber 100 includes an internal space formed therein so that other constituent elements can be stably disposed in the internal space of the reaction chamber 100.

The stage 110 is disposed within the reaction chamber 100. The stage 110 may be fixed in position or displaced in X, Y and Z directions depending on design specifications. In other words, the stage 110 includes a stage base 111 and a stage driving unit 113. The stage driving unit 113 is controlled in operation in response to a stage control signal from a control unit (not shown) so that a stage driving force generated from the stage driving unit 113 moves the stage base 111, and the substrate disposed on the stage base 111 is displaced along with the movement of the stage base 111.

The gas supply unit 120 supplies a precursor and an oxidant to form an atomic layer thin film on the substrate. The gas supply unit 120 supplies the precursor and the oxidant to the substrate S side. The gas supply unit 120 includes a supply line unit (410, 415, 420, 430) that supplies the precursor and the oxidant to the substrate S to allow an atomic layer thin film on the substrate to be formed on the substrate S. The supply line unit (410; 411, 413, 415, 420) includes a precursor supply line unit (411, 415, 420) for supplying a source gas, and an oxidant supply line unit (413, 415, 420). The supply line unit also includes a purge gas supply line unit 430.

In addition, the gas supply unit 120 includes a purge gas supply unit 300 and a source gas supply unit 400. The purge gas supply unit 300 is implemented as an accommodation reservoir that accommodates a purge gas, and can supply the purge gas to reaction chamber 100 through a purge line indicated by a reference symbol A. In addition, the purge gas supply unit 300 can allow the source gas supplied from the source gas supply unit 400 to be transferred to the substrate S through a purge gas control valve 301 operated in response to a purge gas supply control signal from the control unit (not shown). The purge gas control valve 301 is connected to a purge gas supply line unit 303 which is in turn connected to a supply line switching control valve 420.

The source gas supply unit 400 includes a source gas tank unit 430. The source gas tank unit 430 includes a precursor supply tank 431 and an oxidant supply tank 433.

The precursor supply tank 431 supplies the precursor and the oxidant to the combination nozzle unit 130 through a connection line. The precursor supply tank 431 of the source gas supply unit 400 is connected to the precursor supply line unit (411, 415, 420), and the oxidant supply tank 433 of the source gas supply unit 400 is connected to the oxidant supply line unit (413, 415, 420). The precursor supply line unit (411, 415, 420) includes a precursor main line 411, a supply line switching control valve 420, and a source gas common line 415. The oxidant supply line unit (413, 415, 420) includes an oxidant main line 413, a supply line switching control valve 420, and a source gas common line 415. The supply line switching control valve 420 and the source gas common line 415 of the precursor supply line unit (411, 415, 420) and the oxidant supply line unit (413, 415, 420) can be used as a common section. The supply line switching control valve 420 is implemented as a 3-way valve so that it may select either a precursor or an oxidant through the purge gas and selectively transfer the selected one to the combination nozzle unit 130 in the reaction chamber 100. In other words, the supply line switching control valve 420 can be controlled in an alternately switching manner such that the precursor, the oxidant, and the purge gas are supplied to the substrate S in response to a source gas control signal from the control unit 20.

In this embodiment, the description has been made centering on a structure in which a separate transfer gas line is not provided but the purge gas functions as a transfer gas, but the gas supply unit may be configured in various manners depending on design specifications, such as taking a structure of having a separate transfer gas and a structure in which the purge gas is used to transport the source gas including the precursor or the oxidant.

The source gas including the precursor or the oxidant, which is transported by means of the purge gas, is transferred to the combination nozzle unit 130 through a common line 415. The combination nozzle unit 130 is disposed above the stage so as to move relative to the stage. The combination nozzle unit 130 includes a laser core 131, an inner nozzle body 133, and an outer nozzle body 135.

The laser core 131 is disposed at the inside of the inner nozzle body 133 and the outer nozzle body 135. In this embodiment, the laser core 131 is operated in response to a laser output control signal from the control unit (not shown) so that it emits a laser beam to the substrate S through a laser tip 132 formed at a front end thereof. In this embodiment, the laser core 131, the inner nozzle body 133, and the outer nozzle body 135 establish a concentric arrangement structure. A variety of position variation structures may be formed in some cases, but the description will be made centering on the concentric arrangement structure in this embodiment.

The outer nozzle body 135 is an external casing which supports other constituent elements such that they are accommodated and disposed therein, and constitutes one element of a gas transport structure. The inner nozzle body 133 is disposed at the inside of the outer nozzle body 135, and the laser core 131 is disposed at the inside of the inner nozzle body 133.

The space defined between the laser core 131 and the inner nozzle body 133, and the space defined between the inner nozzle body 133 and the outer nozzle body 135 form a gas flow path. In other words, the space defined between the laser core 131 and the inner nozzle body 133 forms a common supply section 416 so that a source gas formed of a precursor and an oxidant for removing the ligands of the precursor, which are transferred from the gas supply unit 120 through the common supply section 416, a purge gas for entirely purging the source gas in the chamber are supplied to the substrate S through a distal end of the combination nozzle unit 130. The common supply section 416 forms at least portions of the precursor supply line unit and the oxidant supply line unit, which are commonly overlapped with each other in that it forms a common supply path of the source gas including the precursor and the oxidant, and the purge gas, and is concentrically arranged at the outer circumference of the laser core 131. That is, as shown in FIG. 2, the space partitioned between the laser core 131 and the inner nozzle body 133 is formed as a common supply section 416.

Further, the space defined between the inner nozzle body 133 and the outer nozzle body 135 is formed as a suction section 417. The suction section 417 is arranged at the outer circumference of the common supply section 416. In this embodiment, the suction section 417 takes a structure in which it is arranged at the outer circumference of the common supply section 416 so as to be concentric with the common supply section 416. In some embodiments, the common supply section 416 and the suction section 417 may have a non-circular specific shape and take a non-concentric arrangement structure to have an eccentric shape of being biased to a specific region, but preferably take a circular-shaped concentric arrangement structure in view of the formation of an atomic layer on a local area of the substrate.

The suction section 417 constitutes a suction line unit. The suction line unit includes the suction section 417, a suction line 418 connected to the suction section 417, and a suction pump 220 connected to the suction line 418. The suction section 417 sucks in gases remaining after the reaction of the source gas formed of the precursor and the oxidant with the purge gas on the substrate S through the space defined between the laser core 131 and the inner nozzle body 133 by a suction force of the suction pump 220 connected to the suction section 417 so that the sucked gases can be discharged to the outside or re-treated for recycling. In other words, the suction section 417 sucks in one or more of the precursor, the oxidant, and a precursor from which the ligands are removed by the oxidant.

In this embodiment, the common supply section and the suction section have a concentric, coaxial structure. The combination nozzle unit 130 takes a structure in that the laser core is disposed at the center of the combination nozzle unit 130, the common supply section is arranged at the inside of the inner nozzle body 133, and the suction section is arranged at the outside of the inner nozzle body 133. For another case, the arrangement positions of the common supply section and the suction section may be vice-versa, but the combination nozzle unit 130 preferably takes a structure in that the suction section circumferentially surrounds the common supply section so that the precursor and oxidant being discharged and injected through the common supply section can be sucked in rapidly and smoothly.

Hereinafter, the operation process of the present invention will be described with reference to the accompanying drawings.

First, the control unit 20 operates the laser core 131 of the combination nozzle unit 130 as shown in FIG. 3. a laser beam is irradiated to a relevant local area of the substrate S through the laser core 131 connected to a laser power supply unit (V) or a laser output unit (not shown) in response to a laser control signal from the control unit 20. In this case, information regarding the output of the laser beam and the local area on the substrate S is transmitted with the laser control signal of the control unit 20. The laser beam irradiation can be modified in various manners such as taking a structure in which a relevant local area is directly divided to irradiate the laser beam to the entire relevant local area in that a light beam emitted from a light source having a high energy density is condensed and irradiated, and in some cases, taking a structure in which the control unit 20 calculates a separate optimized local heating region for depositing an atomic layer on the relevant local area and the laser beam irradiation is performed onto the optimized local heating region.

Thereafter, the control unit 20 applies a supply line switching control valve control signal to the supply line switching control valve 420 to control the valve so that the precursor can be supplied through the common supply section 416 of the combination nozzle unit 130.

The precursor discharged through common supply section 416 is injected to a local area preheated through the laser core 131. In this case, the precursor responds to the preheated local area of the substrate S and is adsorbed to the preheated local area. The precursor forms a chemical reaction with the preheated local area to achieve a chemical covalent bond so that the precursor also forms a chemisorption bond besides a physical adsorption with respect to the substrate S.

In the meantime, during a process in which the chemisorption occurs through the chemical covalent bond with the precursor on the surface of the local area of the substrate S, a precursor that has been discharged and injected through the suction section 417 of the suction line unit but is not adsorbed to the substrate S may be sucked in so as to be recycled.

Then, in some cases, the control unit 20 applies a supply line switching control valve control signal to the supply line switching control valve 420, and applies a purge gas control valve control signal to the purge gas control valve 301 to execute a switching operation of interrupting the supply of the precursor and the oxidant and permitting the supply of the purge gas. By virtue of this purging process, a precursor residue remaining in the common supply section 416 may be removed.

Subsequently, as shown in FIG. 4, the control unit applies the supply line switching control valve control signal to the supply line switching control valve 420 to execute a switching operation of interrupting the supply of the precursor and permitting the supply of the oxidant. The oxidant is composed of water, ozone, oxygen and the like. The oxidant is discharged and injected to the local area of the substrate S through the common supply section 416. The discharged and injected oxidant is removed by reacting with the ligands of the precursor adsorbed to the local area of the substrate S. Only a single atomic layer is deposited on the surface of the local area of the substrate S by such a self-limiting surface reaction so that a uniform ultra-thin film can be formed.

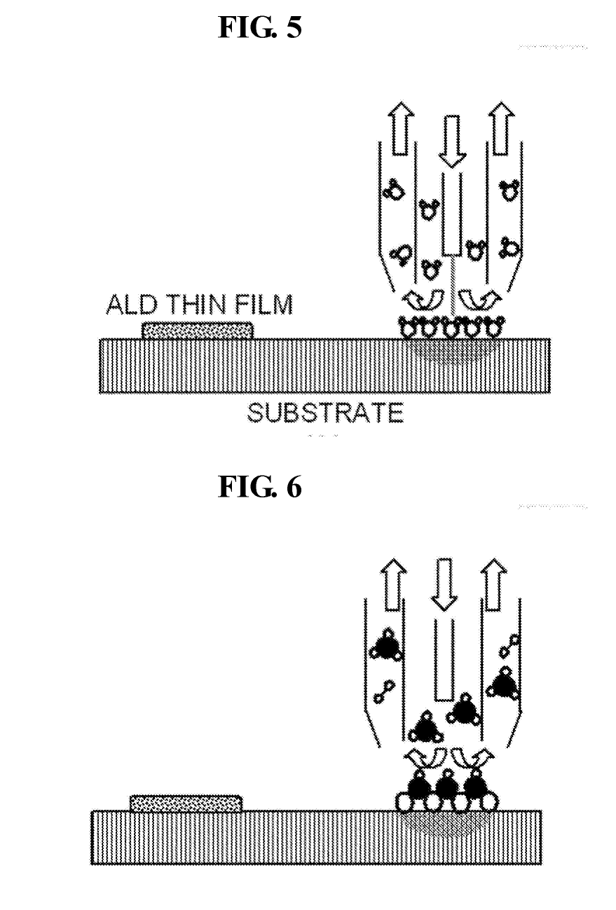

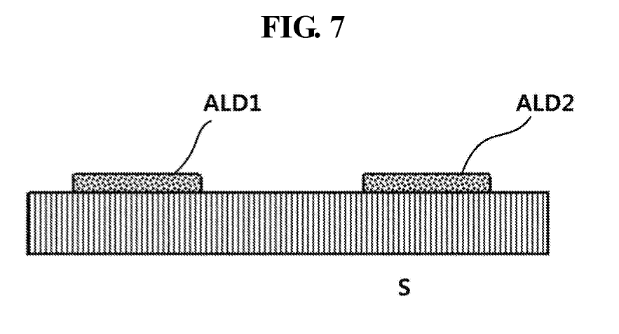

Thereafter, as shown in FIGS. 5 and 6, the control unit 20 controls the substrate or the combination nozzle unit to be transferred to another relevant local area so that a one cycle atomic layer deposition process may be repeatedly performed on the other relevant local area of the substrate S. In addition, as shown in FIG. 7, by virtue of this one cycle atomic layer deposition process, atomic layer thin films ALD1 and ALD2 can be formed on the substrate regions that are selectively formed. In other words, the stage driving unit 113 included in the stage 110 moves the stage 110, more specifically the stage base 111 in response to a movement control signal from the control unit 20, and the combination nozzle unit may execute a repeated atomic layer formation cycle on the relevant local area. Although has been described in this embodiment that the atomic layer thin films ALD1 and ALD2 are formed of the same material on a selective substrate region, in some cases, the atomic layer thin films ALD1 and ALD2 can be modified in various manners, such as being formed of different materials.

### INDUSTRIAL APPLICABILITY

The present invention is an apparatus that performs a rapid, smooth and easy deposition process on a local area during the deposition of an atomic layer thin film, and can be used in an industrial field that requires a local coating besides a semiconductor device.

While the present invention has been described in connection with the exemplary embodiments illustrated in the drawings, they are merely illustrative and the invention is not limited to these embodiments. It will be appreciated by a person having an ordinary skill in the art that various equivalent modifications and variations of the embodiments can be made without departing from the spirit and scope of the present invention. Therefore, the true technical scope of the present invention should be defined by the technical sprit of the appended claims.

1. An area-selective atomic layer deposition apparatus that deposits an atomic layer thin film on the surface of a substrate by supplying a source gas and a purge gas, the apparatus comprising:
a reaction chamber;
a stage disposed within the reaction chamber, and configured to allow a substrate (S) to be disposed on one surface thereof;
a combination nozzle unit disposed above the stage so as to move relative to the stage; and
a gas supply unit configured to supply a precursor and an oxidant to form an atomic layer thin film on the substrate,
wherein the combination nozzle unit comprises a laser core configured to emit a laser beam to selectively locally heat one surface of the substrate, and
wherein the gas supply unit is disposed so as to be at least partially adjacent to the laser core, and supplies the precursor and the oxidant to an area of the one surface of the substrate, which is selectively locally heated by the laser core, wherein the precursor is adsorbed onto the heated area of the substrate, and the oxidant removes the ligands of the precursor.

2. The area-selective atomic layer deposition apparatus according to claim 1, wherein the gas supply unit comprises:
a precursor supply line unit configured to supply the precursor; and
an oxidant supply line unit configured to supply the oxidant.

3. The area-selective atomic layer deposition apparatus according to claim 2, wherein the gas supply unit comprises a common supply section disposed at the combination nozzle unit and configured to form at least parts of the precursor supply line unit and the oxidant supply line unit, which are commonly overlapped with each other.

4. The area-selective atomic layer deposition apparatus according to claim 3, wherein the common supply section is arranged at the outer circumference of the laser core.

5. The area-selective atomic layer deposition apparatus according to claim 4, wherein the common supply section is concentrically arranged at the outer circumference of the laser core.

6. The area-selective atomic layer deposition apparatus according to claim 5, wherein the gas supply unit further comprises a suction line unit including a suction section configured to suck in one or more of the precursor, the oxidant, and a precursor from which the ligands are removed by the oxidant.

7. The area-selective atomic layer deposition apparatus according to claim 6 wherein the suction section is arranged at the outer circumference of the common supply section.

8. The area-selective atomic layer deposition apparatus according to claim 7, wherein the suction section is concentrically arranged at the outer circumference of the common supply section.

9. The area-selective atomic layer deposition apparatus according to claim 8, wherein the precursor supply line unit and the oxidant supply line unit comprise a supply line switching control valve configured to allow the precursor and the oxidant to be alternately supplied therethrough.

10. The area-selective atomic layer deposition apparatus according to claim 8, wherein the stage comprises a stage driving unit configured to move the stage in response to a movement control signal from the control unit.
